(19) United States
(12) Patent Application Publication
(10) Pub. No.: US 2009/0058521 A1
(43) Pub. Date: Mar. 5, 2009

(54) SYSTEM AND METHOD OF DIGITAL LINEARIZATION IN ELECTRONIC DEVICES

(76) Inventor: Andrew D. Fernandez, Sunnyvale, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/848,861

(22) Filed: Aug. 31, 2007

(51) Int. Cl. H03F 1/26

(52) U.S. Cl. 330/149

(57) ABSTRACT

A method, apparatus, and computer program product to reduce nonlinear signal distortion of a primary signal within an electronic device is provided. An example method includes the steps of: applying at least one stimulus signal to excite distortion; analyzing nonlinear effects in the distorted stimulus signal; modeling distortion as a function of the stimulus signal; and creating a correction signal using the distortion model and the primary signal.

### TECHNICAL FIELD

The present application relates generally to nonlinear distortion compensation, and more particularly, to implementing nonlinear time series analysis techniques for distortion modeling.

### BACKGROUND OF THE INVENTION

All analog electronic devices have some component of nonlinear behavior. For some applications, the sum of all device nonlinearities in an instrument's analog front-end limits accurate measurement of a signal. This impairment is of importance because two factors are demanding higher linearity in signal measurement. First, signal sources are becoming more linear. Second, emerging communications applications require wider instantaneous signal bandwidths.

Test instruments are driven to supply greater bandwidths and higher dynamic ranges to enable measurement with minimal error. The drive to reduce the cost of wireless communications equipment has prompted service providers to adopt multi-carrier power amplifiers (MCPAs) in base stations. Multi-carrier power amplifiers are wide bandwidth linear amplifiers used to amplify multiple wireless channels simultaneously, avoiding the problem of combining individually amplified channels. Of course, to test (or characterize) these MCPAs, signal measurement instruments must measure increasingly linear wideband signals quickly. Wider signal bandwidths are required for faster measurements and demodulation of new and emerging communications standards. As an example, nonlinear performance limits dynamic range in today's spectrum analyzers.

Amplifiers in the analog signal chain contribute significantly to an instrument's composite nonlinear behavior. In practice, it is difficult to design an amplifier that is linear over a wide range of amplitudes and frequencies. An amplifier that does not have a linear transfer function characteristic introduces nonlinear distortion in the amplified signal. The amplitude of the input at an instant in time contributes to distortion observed at the output. The distortion at the output increases with larger input signals. This amplitude dependence is often referred to as an AM/AM distortion effect. Distortion may also be introduced if an amplifier creates a phase shift that varies with the signal amplitude (AM/PM distortion). In the frequency domain, distortion products are observed as harmonics and intermodulation products of the original signal. These products occur both inside and outside the bandwidth of the stimulus signal. The distortion behavior may be frequency dependent and/or time dependent. Distortion at one time instant may be dependent on the signal amplitudes at other time instants. These “memory effects” are sometimes ignored in predistortion and distortion compensation methods. Ignoring memory effects, especially for wideband signals, may result in poor correction performance.

Current approaches that mitigate the effects of distortion on signal analysis and generation can be divided in two categories, analog linearization techniques and digital linearization techniques. Many techniques that work in the analog domain involve modifying both the signal and the nonlinear device. In the last decade, a host of digital linearization approaches have also gained acceptance. These methods linearize systems in the digital domain, either by pre-distorting the signal before it passes though a nonlinear element, or by digitally correcting the signal after it has been distorted.

### Analog Linearization Techniques

Analog approaches to distortion reduction include (1) operating the amplifier in a “backed-off” mode, (2) filtering, (3) dithering the input signal, (4) applying feedforward techniques, and (5) applying feedback techniques. General characteristics of these approaches are known in the art.

### Digital Linearization Techniques

Digital approaches to distortion compensation have several general advantages over analog techniques. Analog approaches result in static designs that usually require additional components at the cost of more board space, power, and price. These correction schemes are not easily customizable and may perform more poorly than digital distortion compensation. Digital linearization also allows the analog/system designer to make tradeoffs between linearity and other parameters (such as power or speed). For example, a less linear but lower power amplifier may be designed into a system with the knowledge that its linearity will be improved using digital distortion compensation.

In the case of signal measurement, the digital approach to reducing distortion is slightly different. The measured signal contains distortion and the ‘ideal’ transmitted signal is unknown. Digital distortion compensation typically includes modeling the distortion effects of the analog front-end and subtracting those effects from the input signal. The analog front-ends of signal measurement instruments are usually highly linear. Therefore, one can approximate the ‘ideal’ distortion free system input with the measured signal. Digital distortion compensation is based on accurately modeling nonlinear behavior.

One general method for nonlinear distortion reduction falls under the umbrella of memoryless AM/AM and AM/PM modeling. AM/AM and AM/PM models describe nonlinear behavior between input and output waveforms. These methods tend to fail for wideband signals because they do not model frequency dependent distortion. With a memoryless AM/AM or AM/PM model, gain compression and phase distortion are only functions of the input signal complex envelope amplitude. Distortion that is a function of previous inputs to the system is not modeled.

Volterra series approaches incorporate polynomial models and memory effects. This approach combines a Taylor series and memory (using the convolution operator) to describe nonlinear behavior. While the Volterra series models well describe bandwidth and memory effects (among others), full Volterra models are often cumbersome to implement in real time. As calculations become more complex, the system incorporates more memory, and Volterra approaches typically become prohibitively complex.

Another prior art method for nonlinearity compensation uses error tables (Shown in FIG. 1). Error tables 102 are generated with sinusoidal or pseudorandom calibration signals X[n], X[n−1]. Linearization is achieved by subtracting the compensator table values e[n] from the distorted signal X[n] at 104 to achieve an output x′[n]. Error tables 102 consume a significant amount of memory, which increases with both the dimension of the state space covered and the signal's binary word length. For weak, memory dependent distortion, error tables become prohibitively large. Such solutions also tend to be good only near the table calibration frequency.

One method for avoiding the excessive memory demands of the error table is to model the error with a polynomial. Henrion, et. al. (U.S. Pat. No. 5,583,501) use this method in to capture the memoryless distortion in their system (an analog to digital converter (ADC)). Their polynomial models the error signal (Verr) as a function of the input signal (Vin), and takes the form of:

Verr=f(Vin)=a0Vin+a1Vin2+a2Vin3+ Equation (1)

This is an AM/AM model, with the relationship between Vout and Vin defined by a power series. During calibration, the coefficients (aₙ) of the polynomial are iteratively adjusted to maximize the linearity of a test signal. Unfortunately, as an AM/AM model, this approach provides a fixed compensation over frequency. As a result, the approach is limited to correcting memoryless distortion and is best applicable to the calibration signal.

Velazquez's phase shifted exponentiation method (shown in FIG. 2) extends the polynomial approach by providing an avenue for modeling frequency dependent effects. Such a model typically includes a linear dynamic subsystem 202 (i.e. a filter), followed by a static nonlinearity (i.e., exponentiation) subsystem 204. While this type of model can correct for memory effects, it relies on variable filter coefficients, variable exponentiation powers (as they may not be whole numbers), and additional scaling factors. With all these variables, such a model can be both complex and time consuming to calibrate. In addition, a model of this form can easily grow computationally intensive and become burdensome to implement in real-time. The model also does not include cross terms between the various phase shifted exponentials and does not include any differentiation of the input.

As previously mentioned, both for the Volterra series and other system types, models can easily become overly complex. Complex models typically suffer from the possibility of overfitting, increased calibration time, increased implementation cost, predictability, and extension. Overfitting is a property in which the model is valid only in the immediate range of the calibration signal. For example, an extremely specific distortion model calibrated with a Constant Wave (CW) excitation may prove to be applicable only to a CW sinusoid, and not multitone signals. Extension is the related problem of creating a model that is far removed from reality. Such a model may not well extrapolate to stimuli outside the calibration set, and may not be the most compact or best approximation to the distortion surface.

In addition, the above mentioned prior art methods deal explicitly with distortion compensation in a single ADC system. A system using multiple ADCs to sample the input signal usually requires a novel approach to both linearization and the calibration. In such a system, the bandwidth of the input signal exceeds the bandwidth of an individual ADC. As a result, a distortion model built from the samples of only one ADC will generally fail as the input signal aliases. During calibration of an ultralinear front-end, it is not usually possible to simply treat the interleaved sequence as the original signal because timing errors between the separate ADC paths may exceed the analog distortion levels.

### SUMMARY

Various embodiments of the present invention can be used to overcome the difficulties outlined above. Systems, methods, and computer program products described herein may lead to algorithms for nonlinear corrections enabling hardware with better performance (linearity, stability, etc). These techniques can be applicable to both weakly and strongly nonlinear systems.

One example embodiment can be described as a method to reduce nonlinear signal distortion of a primary signal within an electronic device. The example method can includes applying at least one stimulus signal to the device to excite distortion in the device. The nonlinear effects are analyzed in the distorted stimulus signal. Further, distortion is modeled as a function of the stimulus signal. The method also includes creating a correction signal using the distortion model and the primary signal.

Another example embodiment may be described as an apparatus configured to propagate one or more primary signals. The apparatus includes at least one electronic component configured to compensate for nonlinear distortion caused as a result of a primary signal propagating through the electronic component. The electronic component is designed to compensate for the nonlinear distortion of the primary signal using a time domain modeling technique. It is further configured to apply one or more transforms to the primary signal. Transforms that capture nonlinear behavior are selected and used to approximate error phase space. The electronic component can then produce a correction signal that can be applied to the primary signal, thereby providing a compensated signal.

One example embodiment may be described as an apparatus comprising an electronic component configured to process a primary signal in the time domain. The electronic component includes circuitry to apply one or more stimulus signals to the device to excite distortion. The electronic component further includes circuitry to model distortion as a function of the one or more stimulus signals. There is also circuitry to create a correction signal using the distortion model and the primary signal. In this embodiment, the electronic component is configured to use the correction signal to compensate for nonlinear signal distortion of the primary signal that is caused by the electronic component itself.

One example embodiment may be described as a program product stored in a computer readable medium. The program product is configured to compensate for nonlinear distortion of a primary signal. The example program product includes code for applying one or more transforms to the primary signal. Code for selecting transforms is included to select transforms that best capture nonlinear behavior. The program product further includes code for approximating error phase space and code for producing a correction signal.

Various embodiments of the present invention provide advantages over prior art systems, for instance, an example embodiment is useful for both long and short term memory effects because it may allow for linearization beyond digital distortion compensation methods in the prior art. Additionally, some embodiments lend themselves to a general approach to distortion identification and compensation. Further, as a ‘Black-Box’ approach, such embodiments use minimal a priori assumptions.

The foregoing has outlined rather broadly the features and technical advantages of the subject matter of present application in order that the detailed description that follows may be better understood. Additional features and advantages will be described hereinafter which form the subject of the claims. It should be appreciated by those skilled in the art that the conception and specific embodiment disclosed may be readily utilized as a basis for modifying or designing other structures for carrying out the same purposes of the embodiments of the present invention. It should also be realized by those skilled in the art that such equivalent constructions do not depart from the spirit and scope of the embodiments of the present invention as set forth in the appended claims. The novel features which are believed to be characteristic of the embodiments of the present invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the subject matter of present application.

### BRIEF DESCRIPTION OF THE DRAWINGS

FIG. 1A is a prior art compensation solution utilizing an error table;

FIG. 1B is a prior art compensation solution utilizing phase shifted exponentials;

FIG. 2A is a flowchart of an exemplary method for nonlinear distortion compensation in accordance with an embodiment of the present invention;

FIG. 2B is a block diagram of an exemplary apparatus for nonlinear distortion compensation in accordance with an embodiment of the present invention;

FIG. 3 illustrates an exemplary interleaved ADC system with an upstream nonlinearity;

FIG. 4 is a block diagram of an exemplary overall nonlinear distortion compensation system in accordance with an embodiment of the present invention;

FIG. 5 is a block diagram of an exemplary circuit that implements nonlinear distortion compensation in accordance with an embodiment of the present invention;

FIG. 6 is a block diagram illustrating an exemplary overall distortion model in accordance with an embodiment of the present invention;

FIG. 7 is a block diagram illustrating an exemplary distortion model with reduced embedding functions in accordance with an embodiment of the present invention

FIG. 8 is a block diagram illustrating an exemplary overall distortion model in accordance with an embodiment of the present invention;

FIG. 9 is a chart depicting an exemplary basis function tradeoff curve in accordance with one embodiment of the present invention;

FIG. 10 is a block diagram and chart depicting an exemplary setup to stimulate nonlinear behavior in a tone calibration process;

FIG. 11 is a block diagram and chart depicting an exemplary setup to stimulate nonlinear behavior in a tone calibration process;

FIG. 12 is a block diagram of an exemplary circuit for single channel linearization for a 2-way interleaved system in accordance with an embodiment of the present invention;

FIG. 13 is an illustration of an exemplary top level digital nonlinear correction block diagram according to an embodiment of the present invention;

FIG. 14 depicts an exemplary prototyped NLC algorithm according to an embodiment of the present invention;

FIG. 15 depicts an exemplary block diagram of a computer system which is adapted for use with an embodiment the present invention.

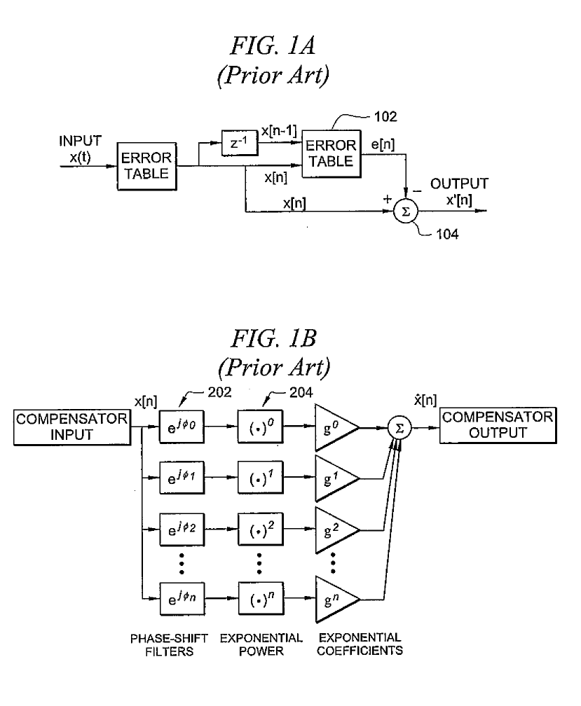

### DETAILED DESCRIPTION

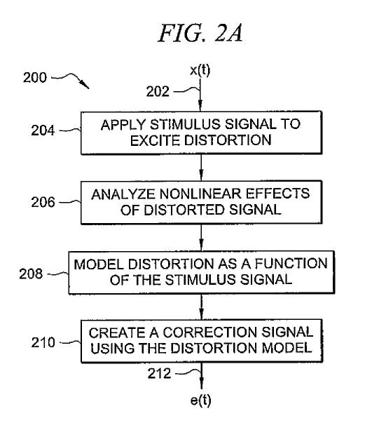

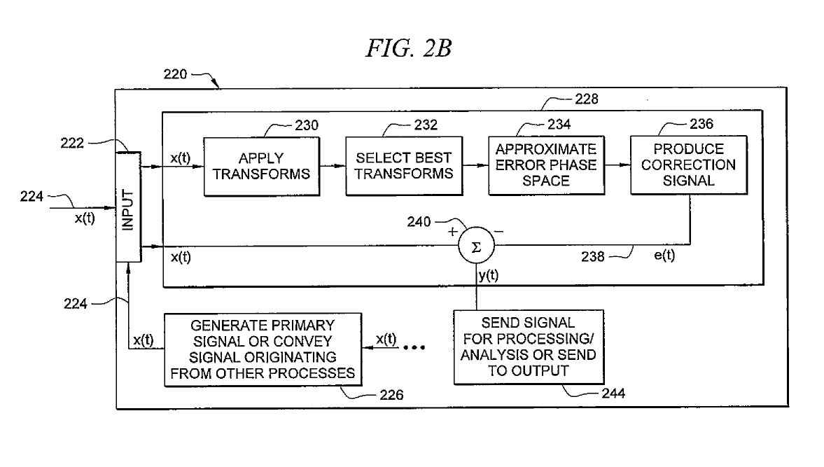

FIG. 2A illustrates an exemplary method for reducing nonlinear signal distortion 200 of a primary signal x(t) 202 within an electronic device. It is noted that the primary signal 202 can be received by the electronic device at an input via a direct connection, RF connection, infra red transmission, or by any other means to receive a signal. The primary signal 202 may also have been generated by the electronic device, or propagating through as part of another process. It may also be advantageous to sample the primary signal with multiple analog to digital converters (ADC) in the case of primary signals propagating in an interleaved ADC system.

The method 200 applies a stimulus signal to excite distortion 204. The stimulus signal is applied to the electronic device and may take the form of one or more sinusoids, preferably a signal with the same statistical qualities of the typical primary signal, or may even be the primary signal itself. The use of a waveform, such as the primary signal, as the stimulus often has the advantage of leading to a distortion model which is built for signal statistics identical to that typically seen by the device. In general, any stimulus that assists in adequately capturing the nonlinearity caused by the electronic device can be used.

Nonlinear effects in the distorted primary signal 202 are analyzed at step 206. In this step the response from step 204 is analyzed to separate the linear effects from the nonlinear effects. As an example, for the case of sinusoidal tone stimuli, an ideal (distortion free) sinusoidal stimulus may be subtracted from the measured distorted response. Although the amplitude and phase of each tone may not be known a priori, a fitting process (such as Least Squares) can identify both amplitude and phase for stimulus tones. With the frequency, amplitude, and phase known, the analytical representation of the stimulus is known. This ‘ideal’ stimulus is subtracted from the measured distorted response to yield a residual signal. The residual is the error due to nonlinear distortion. Compensating for linear effects, if desired, can be performed using known methods and is outside the scope of the present application.

Once the nonlinear effects are identified, the nonlinear distortion can be modeled as a function of the stimulus signal, at 208. The input stimulus is transformed to create a set of “embeddings”. These transforms may include in some embodiments: the first time derivative of the primary signal, the second time derivative of the primary signal, the integral of the primary signal, the absolute value of the primary signal, one or more time delays at various times of the primary signal, and/or the like. It is sometimes useful to choose an embedding that is linked to one or more physical phenomena. For example, slew rate of an amplifier may be modeled as a time derivative. A compact model for the distortion is created from the set of generated embedding functions. Modeling distortion in step 208 can be implemented in a variety of ways, including approximating the distortion (error) function using a polynomial, a lookup table, interpolated look up table, a neural network, or any combination thereof. The distortion function is a function of these embeddings. Any efficient means to approximate an error function can be implemented in this example.

A correction signal 212 is then created using the distortion model at 210. This correction signal can then be applied to the original primary signal, thereby compensating for nonlinear distortion effects that have been introduced by the electronic device. In the case of signal generation, method 200 may be used to compensate for nonlinear distortion effects that occur subsequent to the summation of the correction signal with the primary signal. This process is called “pre-distortion” because the correction signal is introduced to the primary signal prior to the distortion.

FIG. 2B shows a block diagram for an exemplary apparatus 220 configured to propagate one of more primary signals 224. The apparatus 200 has an input block 222 designed to receive or relay a primary signal x(t) 224. The primary signal 224 is received from an external source via an RF transmission, direct cable connection, infra red transmission, or the like. The primary signal may also originate/be generated from within the apparatus 220 or be propagated from another portion within the apparatus at block 226.

The apparatus 220 includes at least one electronic component 228 configured to compensate for nonlinear distortion of the primary signal 224. The electronic component 228 is designed to compensate for nonlinear distortion caused as a result of a primary signal 224 propagating through the apparatus 220. The electronic component 228 is configured to compensate for a primary signal 224 that is interleaved using multiple analog to digital converters. Additionally, the electronic component 228 compensates for the nonlinear distortion of the primary signal 224 using a time domain modeling technique. The electronic component receives the primary signal x(t) at block 230 where one or more transforms are applied to the primary signal. Transforms that best capture nonlinear behavior are then selected at 232. The transforms may take a variety of forms, such as a first time derivative of the primary signal, the second time derivative of the primary signal, the integral of the primary signal, the absolute value of the primary signal, one or more time delays at various times of the primary signal, and the like. Any transform that assists in adequately capturing the nonlinearity caused by the electronic component can be used in various embodiments. Further, as discussed above, it is sometimes useful to choose a transform that is linked to a physical phenomena.

Thereafter with the selected transforms, error phase space is approximated at block 234. Error phase space may be approximated using a polynomial, a lookup table, interpolated look up table, a neural network, or any combination thereof. Any efficient means to approximate the error phase space can be implemented at block 234 in some embodiments. Once the error phase space is approximated, at block 236 the electronic component 228 produces a correction signal 238 which is subtracted from the primary signal x(t) at 240. Thus, a compensated signal y(t) is provided by the electronic component 238. Once a compensated signal is provided the signal can be sent for processing or analysis or sent to an output to be transmitted (see block 244).

The path that the signal takes in block 244 typically depends on the nature of apparatus 220. For example, in one embodiment apparatus 220 is a network analyzer configured to receive one or more primary signals at 222 and analyze the signals without causing undue nonlinear distortion. This embodiment enables highly accurate analysis of signals for which it is generally more difficult to obtain precise measurements due to the type of signal being measured and limitations of standard equipment.

In another example embodiment the apparatus 220 is a digitizer configured to propagate the one or more primary signals while causing minimal nonlinear distortion within the digitizer. It is noted that a digitizer may be part of a network analyzer as discussed above, or any other apparatus which sends of receives signals.

In another example embodiment, the apparatus 220 includes a radio wave transmitter and is configured to generate and transmit one or more primary signals without causing undue nonlinear distortion within the apparatus. Further, in yet another embodiment the apparatus 220 comprises a radio wave receiver configured to receive the one or more primary signals without causing undue nonlinear distortion within the apparatus.

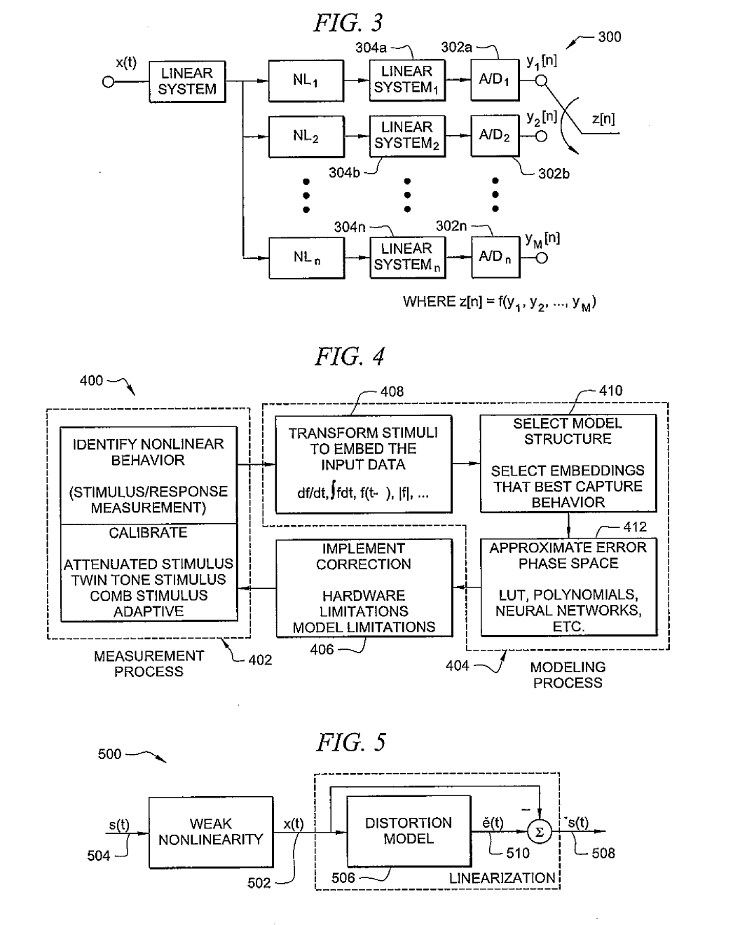

FIG. 3 illustrates an exemplary electronic device 300 composed of multiple time interleaved analog to digital converters (ADCs) 302a-n. The device 300 has several parallel paths, containing both linear systems (such as analog filters) and nonlinear elements 304a-n, NL₁, NL₂, NLₙ. The example embodiment of FIG. 3 linearizes the multiple input paths in electronic device 300 using the following technique. First, it models the linear systems in each path and discerns between the linear and nonlinear contributions of each system. The general approach has been discussed above with regard to FIGS. 2A and 2B.

One additional advantage to this approach, not previously discussed, is its facility for measuring distortion in a time interleaved ADC system. In such a system, each component ADC 302a-n has an analog bandwidth greater than or equal to M*Fs/2. (Where M is the number of ADCs in the system and Fs is the ADC sample rate.) In such a system, the input signal with frequency content above Fs/2 will appear aliased to a lower frequency between 0 and Fs/2 when observed using the samples of one ADC alone. This effect, if not corrected, can result in an improperly constructed representation of the distorted signal, and hence an improperly measured error. However, by utilitizing samples from all ADCs 302a-n, it is possible to reconstruct a frequency estimate of the original (possibly super Nyquist) signal, place it within a given Nyquist zone, and proceed to fit an analytical representation of the signal. Hence, it is possible to recover a (possibly aliased) error signal for each path, as well as to create independent distortion models for the nonlinearities 304a-n in each path. In addition, it is possible to generate embeddings of fractional sample delays (of n*1/M) of the measured signal yₘ[n], by using the adjacent samples: . . . yₘ₋₂[n], yₘ₋₁[n], yₘ₊₁[n], yₘ₊₂[n] . . . .

In such a system, determining an analytical function of the stimulus for modeling purposes may allow one to bypass the bandwidth limitations imposed by a multiple ADC system. In this example, each ADC has a unique signal path. As a result, the nonlinear distortion seen by one ADC may differ slightly from another ADC in the system. It is often desirable to characterize and correct for nonlinear distortion in each ADC path independently. Unfortunately, since each ADC operates at a fraction of the front-end bandwidth, it is not generally possible to capture the response of a single ADC path at the full system sample rate. This can make it difficult to model time derivatives, integrals, arbitrary delays, etc. (which are normally functions of the full bandwidth signal). However, if one determines an analytical function of the stimulus, the subsequent model fitting and evaluation process for independent ADC paths is usually simplified.

Having broadly described the linearization techniques and systems above according to example embodiments of the present invention, specific examples of use and implementation of the subject matter of the present application are given below using a digitizer. However, it should be appreciated that various embodiments of the present invention are not limited to exemplary features and functionality described herein, as the approaches may be applied to compensate for nonlinear distortion of signals in both signal receivers and signal sources, along with many other types of components.

Referring to FIG. 4, the time domain modeling approach to distortion compensation is based on applying a stimulus waveform to excite distortion. The response is then analyzed to separate the linear effects of the system from the nonlinear effects. Once the nonlinear effects have been identified, one may then model distortion as a function of the stimulus signal. A correction signal is created using only the distortion model and the (imperfect) received signal.

The construction and operation of this nonlinear compensation approach 400 can be described in 3 separate stages. The procedure shown below includes measurement challenges 402 and modeling challenges 404 to address when implementing a form of distortion compensation. The three steps of this approach: modeling 404, measurement 402, and implementation 406 are discussed below in further detail.

### Modeling Process

Various embodiments include accurately and compactly modeling the observed nonlinear distortion behavior. The distortion may exhibit dependence on amplitude, phase, memory, signal bandwidth, modulation, frequency, and the like. The modeling approach described herein utilizes techniques from Nonlinear Time Series Analysis (NILTSA). The exemplary modeling process 404 begins by applying transform stimuli to embed the input data at block 408. A model structure is then created by selecting which embeddings best capture nonlinear behavior at block 410. The phase error space is then approximated using a look-up table, neural networks, polynomials, and/or the like at block 412.

The quality of the model typically impacts the quality of linearization. FIG. 5 illustrates an example block diagram 500 for linearization using a model of the nonlinear behavior. Since various embodiments are highly linear, the received signal x(t) 502 is a good estimate of the stimulus s(t) 504. Thus x(t) 502 is the input to distortion model 506. The output 508 of model 506 is an estimate of the error between s(t) 504 and x(t) 502. Therefore, the distortion model 506 is a function of x(t) 502 that estimates e(t) 510. The model 506 is implemented digitally since the received signal, x(t), is usually digitized. The received signal, x(t) 502, and the true error (or sufficiently good approximation), e(t) 510, is used to build the distortion model 506.

1) Transform Stimulus to Create Embeddings of the Data

As is usually appropriate in NLTSA, a typical model is built by first transforming the stimuli at block 408 by taking derivatives, time delays, absolute values, and/or the like. These transforms of known stimuli may be used in conjunction with the stimuli themselves to create a sufficiently rich model to fit the observed error. There are methods commonly used to identify the degree of embedding necessary to adequately capture the nonlinearity, such as nearest neighbor, and the like. It is sometimes appropriate to purposely pick particular transforms that are linked to physical phenomena. For example, slew rate limiting behavior of an amplifier may be modeled by a time derivative.

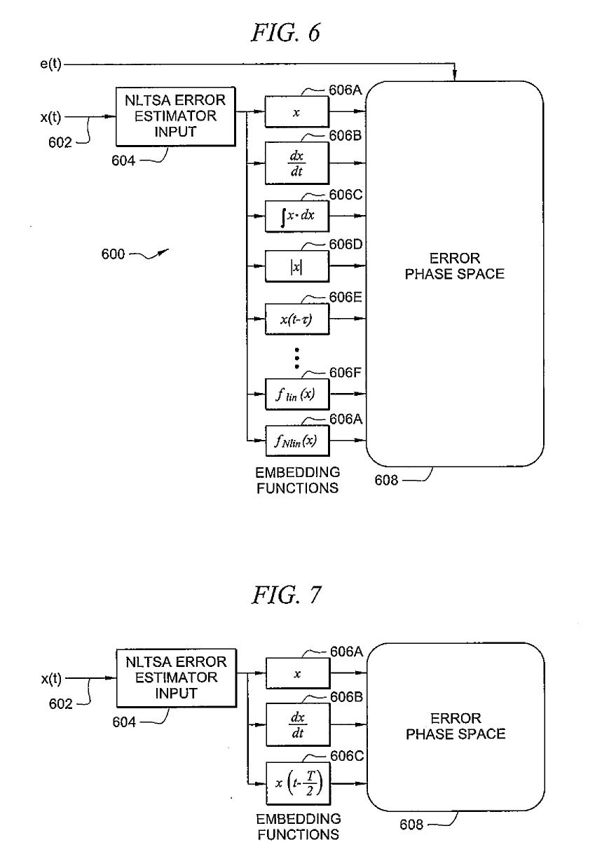

FIG. 6 illustrates a generalized block diagram 600 of a portion of the model wherein embedding functions are generated. An input signal x(t) 602 is sent to an NLTSA error estimator input block 604. The signal is then sent to various embedding functions 606A-F. In various embodiments, the embedding functions can include anything that is helpful for capturing the nonlinearity as discussed above. The various transformed signals are then output to an error phase space block 608.

2) Select Model Structure

Once these embeddings have been created, one must select a subset of these to create a practical model. The set of embedding functions used may be narrowed through examination of the physical properties of the system, compensator implementation practicalities, and consideration for which subset best enables a compact functional approximation of the error phase space 608.

Various delays, derivatives, integrals, absolute values, and other transforms of the analytical waveform can be used as embedding functions by various embodiments for a polynomial distortion model. These inputs include the present sample, previous sample (5 ns), previous sample (10 ns), first derivative, and second derivative. Using these inputs one can predict the error between present sample at the receiver and the analytic present sample. Two metrics commonly used to measure the model's accuracy are the mean squared error and standard deviation of error between the observed distortion e(t) and predicted distortion, ê(t).

In some embodiments the number of inputs to distortion model 506 may be reduced substantially without significantly compromising accuracy. Further, the analytic slope and analytic present sample are factors that affect model 506. An addition of analytic delay also typically improves the modeling accuracy. However, including both 5 ns and 10 ns delayed samples are not necessary to realize this improvement. A model which includes the 5 ns delayed analytical waveform has a standard deviation of error approximately 15% lower than one with only a 10 ns delay. In addition, models with only delays or derivatives as inputs tend to perform more poorly than models based on a mix of delays and inputs. A model which includes only the analytic waveform and first and second derivatives has a standard deviation of error approximately 15% greater than a comparable model with mixed delay and derivative terms. A model based on only the present and delayed analytical waveforms is often worse (about 100% increase in standard deviation of error).

From experimentation with data from the analyzer, a function of the form

$$f ( x ( t ) , ( t - τ ) , \frac{d x}{d t} ) ,$$

where τ=5 ns, has been found to well approximate e(t) in some embodiments. Thus, the result is shown in the simplified block diagram of FIG. 7 having three embedding functions 606A-C corresponding to the function above.

3) Approximate the Error Function

Once the relevant dependent variables in the error model have been determined, the error trajectory is approximated as a function of those variables. An approximation is used in order to reduce the hardware cost and increase the speed of implementing nonlinear compensation. The approximation of the overall error behavior may take the form of a polynomial, look up table, interpolated look up table, neural network, and the like.

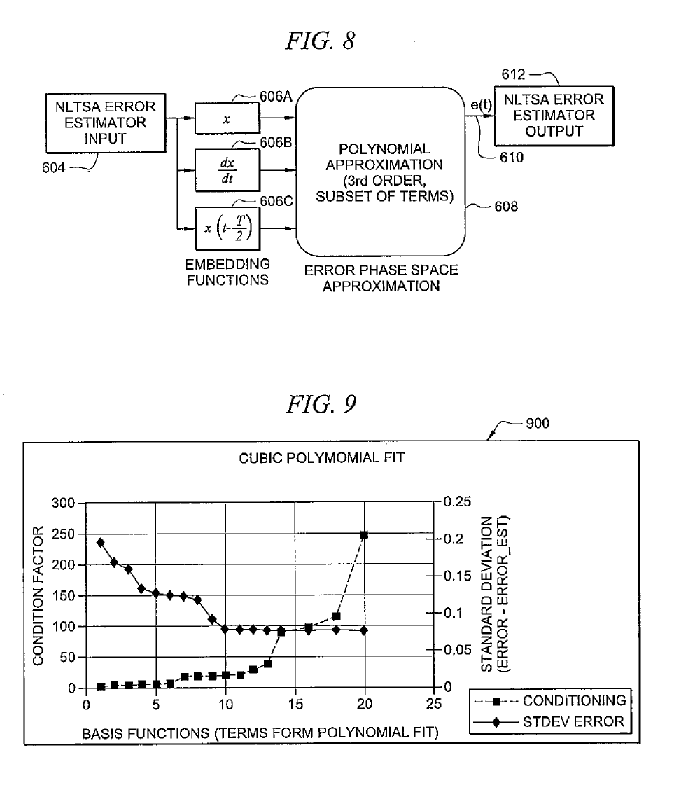

In one example embodiment polynomial approximation is used to approximate the error phase space 608. FIG. 8 shows the block diagram of FIG. 7 with the error phase space block 608 implemented by using a polynomial approximation. Once the polynomial approximation is implemented an error signal e(t) 610 is output to the NLTSA error estimator block 612.

An advantage of polynomial approximation in some embodiments is that it simplifies hardware implementation and avoids the calibration and memory costs associated with a error table. The distortion observed in an example ultra-linear receiver currently used is termed “weak”. In a weakly distorting system, second and third order harmonics and intermodulation products dominate. Thus, a third order polynomial is chosen to approximate the error phase space 608. Polynomials of order less than three typically cannot model spectral re-growth near the fundamental frequency. For this example system, higher order polynomials typically do not substantially improve the quality of a third order polynomial fit and suffer from a greatly increased model size. However, various embodiments are not limited to using any particular order polynomial.

The order of a polynomial is the maximum power of each variable xᵢ, (i=1, . . . , d), where d=dim(x) is the total number of variables in the polynomial. For example, the second order polynomial of two variables, x₁ and x₂, has the following form:

f(x₁,x₂)=c₀+c₁x₁+c₂x₂+c₃x₁x₂+c₄(x₁)²+c₅(x₂)² Equation (2)

If m is the order of the polynomial, then the total number, n, of coefficients (c₀, c₁, . . . ) is given by the formula:

$$n = \frac{( d + m ) !}{d ! m !} .$$

The number of terms in a polynomial approximation grows quickly with the polynomial order and number of variables.

Given the functional form of the model, it is possible to use batch methods such as least squares techniques to solve for the optimal model coefficients in the least squares sense. Let each column in a given matrix A be generated by one term of the polynomial model. Then solve for the coefficient vector, x, in the matrix equation y=A*x such that ∥Ax−y∥ is minimized. The least squares solution to solving for the coefficient vector x is: x_{lS}=(A^{T}A)⁻¹ A^{T}y. One may also utilize Least Mean Square (LMS), Singular Value Decomposition (SVD), brute force, or possibly Recursive Least Squares (RLS) to determine calibration coefficients and prune a comprehensive model into one with the dominant distortion terms.

In some cases, it may be difficult to compute the least squares solution directly. The task of inverting the square symmetric matrix (A^{T}A)⁻¹ may be streamlined if contributions from eigenvalues that are smaller than a given level are removed. The Principal Component Method (PCM) can improve the matrix inversion problem. For example, Let G=(A^{T}A). The matrix to be inverted, G, first is diagonalized: G=LDL^{T}, where L is an orthogonal matrix, and D is the diagonal matrix. The diagonal matrix is ordered in a descended way: D₁₁≧D₂₂≧D₃₃≧ . . . Then all elements with Dₗₗ/D₁₁<ε are replaced by zero. The new diagonal matrix D₀ substitutes the original one, D, in formula for inversion of G.

In an example technique to balance model complexity and accuracy, a model error with a third order polynomial function of the analytic waveform, a 5 ns delayed analytic waveform, and the analytic slope is chosen. A third order polynomial function of three variables contains twenty terms. The twenty coefficients of this model are recovered with a simple least squares fit of the input variables to the observed error. Not all of these terms provide unique information in the model. To further reduce the complexity of the model, it is possible to eliminate the terms with the smallest coefficients and then re-fit. It is further possible to balance the conditioning (κ=σₘₐₓ/σₘᵢₙ) of the matrix formed by the columns of each term in the model and the accuracy of the fit to determine the number of desired terms.

FIG. 9 illustrates a chart plotting a basis function tradeoff curve 900. This method does not always yield an identical model with different data sets, but does suggest the optimal number of terms to use. In this case, nine terms appear to be close to the ideal size of the model.

A brute force approach can also be used to identify the optimal terms to retain from the larger model for the best fit. Using a brute force approach it is possible to perform fits of all possible subsets of seven, eight, and nine terms of the twenty term model. As before, the subset of terms with the lowest standard deviation of error was considered to be the best-fit model. The brute force approach yields models that are similar, sharing many terms from fits with smaller subsets. A model with eight of the original twenty terms identified with this approach exhibits a standard deviation of error comparable to the ten-plus term models plotted in FIG. 9.

The current model is a third order polynomial function of the analytic present sample (X), analytic slope (Y), and the analytic 5 ns previous sample (Z). The coefficients in equation 3 below apply a fit of the normalized variables to normalized error. (Normalized by the experiment with the largest error).

Error=c₁Y+c₂X²Y+c₃Y²+c₄Y³+c₅XZ+c₆X²Z+c₇YZ+c₈Y²Z Equation (3)

4) Add System Modifications

Physical systems and instruments often contain high order linear filters. In some embodiments The effect of these filters may be incorporated into the compensator framework above by inserting approximation filters before and/or after the NLTSA compensator. For example, if the compensator is designed to correct for a nonlinearity upstream of an anti-alias filter, it is possible to remove the linear effects of the anti-alias filter with a digital filter inserted before the compensator.

The compensator design is usually simpler for a smaller range of signal behavior. In the case of the present example digitizer, one area of interest includes the 50 MHz to 90 MHz signal band. The stimulus signals occupied this band. However, in normal operation, an instrument is typically exposed to signals outside the compensator calibration range. In such embodiments, a digital filter may be inserted before the error estimator in the error compensator. This filter limits correction to input signals which lie in the range of the error compensator.

### Measurement Process

Nonlinear distortion is usually difficult to measure in highly linear systems. Typically, the stimulus waveform is not known to a high degree of accuracy (after all, the receiver is imperfect.) In addition, signal sources are generally imperfect as well. Therefore, the desired stimulus may be different from the actual stimulus. An additional measurement challenge in such systems is to ensure that measurement or calibration techniques are applicable to receivers which combine multiple receive paths, each with different nonlinear behavior. The ToneCal technique (described below) that has been used to overcome many of these issues.

1) ToneCal [Tone Based Calibration]

ToneCal calibration typically makes use of analytic fit to try arbitrary transforms/mappings for model building (NLTSA type), and to identify nonlinear distortion in the front end. With analytic fit and knowledge of calibration frequency, it is possible to use simple low distortion stimuli to generate models for independent receiver paths in some embodiments, as described in the following examples.

Once response to the above stimuli is obtained, a least squares fit on I or Q channel data is performed to determine the analytical stimulus waveforms. These analytical waveforms may then be differentiated and or delayed for additional inputs to the distortion model. The analytical waveform fit has the property of averaging out the noise present in the sampled data to better determine the error due to distortion. Since the fit is based on either the I or Q samples the distortion may be characterized in each channel independently.

The least squares fit lowers measurement noise and allows separate modeling of distortion in the I and Q channels. This approach also allows the targeting of distortion downstream of the anti-alias filter (AAF) by judiciously choosing the stimulus. The error between the analytical stimulus function and the receiver samples is often assumed to be due to distortion generated after the AAF.

In one example a two-tone signal is presented to the digitizer on I/IF port. The signal generators and digitizer share the same 10 MHz reference. The level of each tone is −9 dBfs. Digitizer is set to Rng=−9 dBm. 20 K samples from the I ADC and 20 K samples from the Q ADC are captured and saved.

Two different types of two-tone signals to generate the distortion are used in this example. Each type of signal excites the nonlinear distortion in different ways. Both types of stimuli result in harmonics observed outside the AAF and, therefore, both excite nonlinear behavior after the AAF.

a.) Two Tones with Fixed Δf and Varying Center Frequency

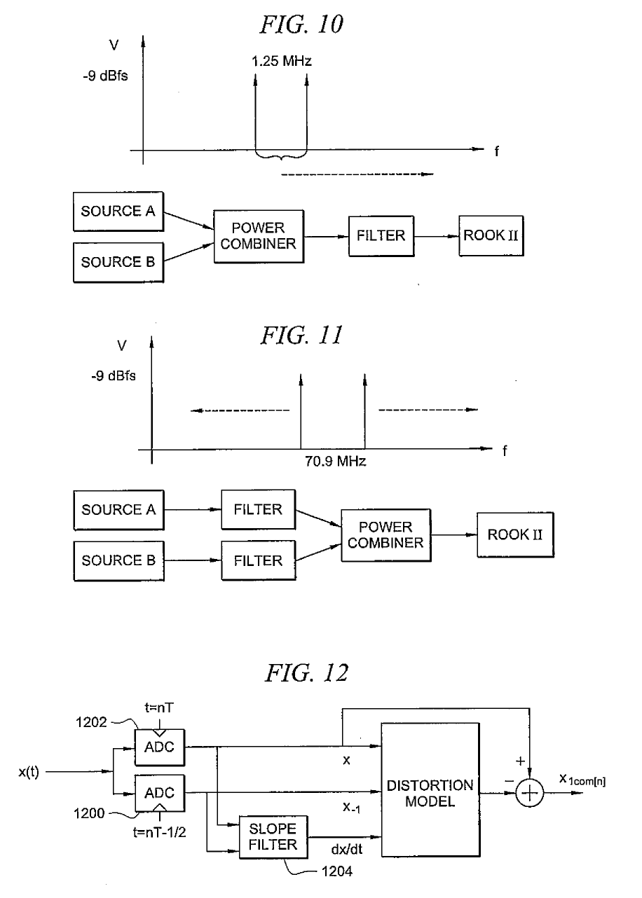

This type of signal excites frequency dependent nonlinear behavior. Two tones with a fixed Δf of 1.25 MHz can be applied to a system, such as the one shown in FIG. 10. In this example, the center frequency of the tones is changed from approximately 50 to 90 MHz in twenty steps.

b.) Two Tones with Varying Δf and Fixed Center Frequency

This stimulus excites signal bandwidth dependent distortion. Two tones with a fixed center frequency of 70.9 MHz can be applied to a system, such as the one shown in FIG. 11. In this example, the frequency separation is changed from 2 to 40 MHz in twenty steps.

Other steps taken in various embodiments of the invention include a least squares fit to collected data, lock oscillator references for the signal sources and signal receiver, and recover analytical versions of the two tones that were injected. Sinusoids that pass through a linear system may encounter a change in amplitude and/or phase. By fitting the sinusoids at the output of front-end, any linear effects of the front-end can be accounted for. A time domain error waveform may be created by subtracting the analytical stimulus from the measured response. Points in the error waveform are introduced by either noise or nonlinearities. Noise may introduce multiple error values for the same point in the phase space. In an example system, error is selected to be a function of x, dx/dt, x[n−½]. (where n represents the samples from one ADC in the system). Multiple error values for the same point in the phase space are averaged to generate a less noisy estimate of distortion. This error waveform and the analytic function can be used to evaluate possible embeddings and select the appropriate functional approximation to the measured distortion. The decision to model the ‘error’ rather than the entire distorted signal reduces the numerical precision required for model coefficients. In addition, modeling based on an error term introduces fewer numerical errors in the calibration and model building process.

As previously mentioned, this example method allows the characterization of an ultra-linear system through the use of two simple signal sources. While generating distortion free complex signals can be difficult, it is possible to generate spectrally pure single tones. The stimuli for this ToneCal approach does not contain distortion products. Using this approach, distortion introduced by the source is identified as originating in the receiver. This method also allows bypassing of the bandwidth limitations imposed by a multiple ADC system. In such a system, each ADC has a unique signal path. As a result, the nonlinear distortion seen by one ADC may differ slightly from another ADC in the system. It is possible to characterize and correct for nonlinear distortion in each ADC path independently. However, since each ADC operates at a fraction of the front-end bandwidth, it is not usually possible to capture the response of a single ADC path at the full system sample rate. This often makes it difficult to model time derivatives, integrals, arbitrary delays, etc. (which are normally functions of the full bandwidth signal). However, if one determines an analytical function of the stimulus, the subsequent model fitting and evaluation process for independent ADC paths is often simplified. This approach was used to determine the final digitizer distortion model.

2.) Attenuated Stimulus Calibration Approach

Attenuated stimulus calibration (ASCal) is a method of calibrating a nonlinear model with an imperfect (nonlinear) signal source. For more information on this subject, see copending US patent application titled “Nonlinear Model Calibration Using Attenuated Stimuli” Ser. No. 11/299,011, filed on Dec. 9, 2005, which is herby incorporated by reference. The ToneCal approach described above uses a priori knowledge of the calibration signal (frequency and number of tones). In contrast, ASCal provides a ‘blind’ approach to nonlinear equalization. This approach relies on the fact that an attenuated stimulus will usually generate lower levels of nonlinear behavior in a DUT relative to the original stimulus. If there is a perfectly repeatable source, then one could compare the stimulus and attenuated stimulus signals. Nonlinear differences can be attributed to the DUT distortion if one can assume that the attenuator is highly linear (a reasonable assumption). This information may be subsequently used to model and calibrate the nonlinear response of our system.

3.) Other Approaches

Some embodiments can be adapted to perform the calibration sequence with a multi-tone comb filter centered at the frequency range of interest. However, this test signal approach is often inferior to other embodiments in that it generally lacks the signal diversity available with the ToneCal or ASCal methods. Since an ultra linear comb signal is used (but difficult to generate), this approach typically is not ideally suited to in-the-box calibration.

If the calibration signal is known (and relatively distortion free), the fitting procedure may also be accomplished in the frequency domain. From the response, one may determine an analytic calibration signal, compute the expected distortion, transform error and distortion basis functions to frequency domain and perform a LS fit therefrom. This approach can be advantageous in that it often reduces the complexities implicit in time domain fit and applies constraints in frequency domain for a more targeted model.

### Implementation and Results

This section describes an example hardware implementation of an NLC algorithm. It describes both the procedure and some details of the design. It concludes with plots of dynamic range improvement demonstrated by NLC running in real time on the digitizer.

1.) Real-time Distortion Correction in the Time Domain

As mentioned in previous sections, an exemplary method of distortion compensation estimates amplifier error based on the received signal. This error estimate is subtracted from the present signal to compensate for distortion. One typically models nonlinear error as a function of the input signal. Unfortunately, in an instrument, the input signal is unknown. However, when modeling weak nonlinearities, the response itself is often a reasonable estimate of the distortion free input signal. Therefore the post-distortion signal may be used in a model to estimate error in various embodiments.

An outline of an example correction scheme implemented in MATLAB™ and translated to digital hardware is shown in FIG. 12. Corrections are applied to both ADC outputs. For simplicity, the illustration in FIG. 12 outlines corrections for the top ADC in an interleaved ADC system.

To estimate the error using the polynomial model above, it is possible to first convert the analytic model terms to those easier to implement. Instead of an analytic present sample, the uncalibrated ADC sample from digitizer is used in this example embodiment. The analytic 5 ns delay may be approximated by the (uncalibrated) alternate ADC 1200 sample in the digitizer's ping-ponged ADC scheme 1200 1202. Finally, applying a derivative filter 1204 to the uncalibrated IF formed by interleaving the I and Q samples yields an approximation to the analytic slope model term. At present, these approximations perform similarly (<1 dB difference) to the analytic model terms on two tone data sets. In practice, it is possible to re-fit the data using the approximated terms (rather than the analytic terms) to find better-suited coefficients.

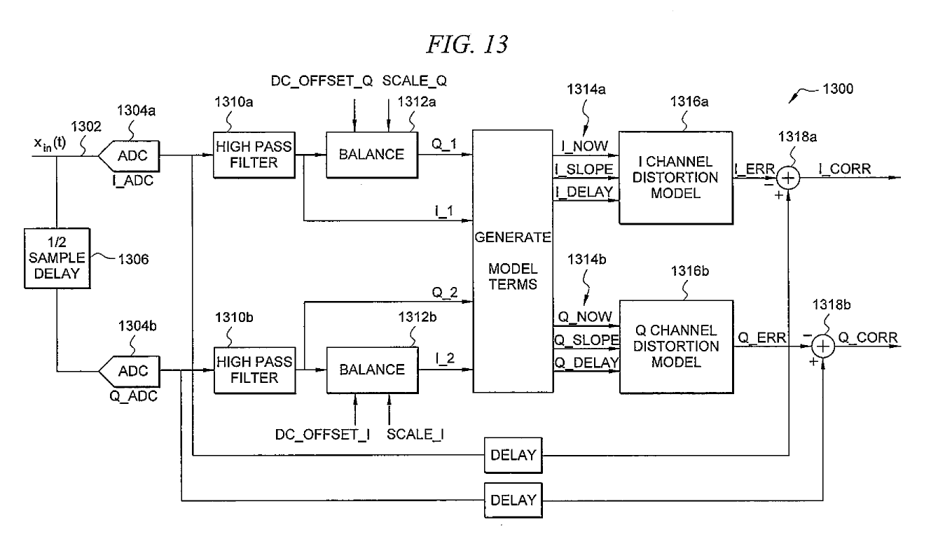

In this example, the algorithm is implemented in MATLAB's Simulink™ in the form of DSP blocks provided by Xilinx's System Generator™. These blocks map directly to common hardware device language definitions that may be implemented compactly in an field-programmable gate array (FPGA). System Generator™ provides a means for simulating and prototyping signal processing algorithms on FPGA platforms. Simulations based on these DSP blocks are bit and cycle accurate. The Simulink™ block diagram for the NLC algorithm is shown in FIG. 13. In this embodiment the data is allowed to flow at the system's 100 MHz rate while balancing the quantization error incurred with the physical area of the implementation. The model structure implemented is fixed, however all coefficients (including channel balancing) are variable (see FIG. 13).

The block diagram of FIG. 13 shows an exemplary embodiment of a real-time implementation of the NLC algorithm 1300. In time-interleaved mode, the input signal x(t) 1302 is sampled by the I ADC 1304a at a rate of Fs (or 1/Ts), and sampled by the Q ADC 1304b after a ½ sample delay 1306. The example time interleaved sampling approach used herein doubles the system sampling rate. Samples from I and Q that are inputs to the nonlinear model are sent through high pass filters 1310a 1310b. Due to previous measurements the distortion occurs primarily between 50 and 90 MHz. The high pass filters 1310a 1310b ensure that the distortion model is active for the region of interest. Following the high pass filters 1310a 1310b, model terms are generated. In this embodiment, during channel balancing step 1312a 1312b, the sample from the alternate channel is scaled and offset such that is more closely approximates the sample on the original channel, delayed by ½ sample. The samples from both channels are filtered to estimate the time derivative of the channel. As a result, for the I channel and for the Q channel, the ‘now’, ‘slope’, and ‘delayed’ model terms 1314a 1314b are created. These three terms are inputs to the nonlinear model (polynomial representation) block. There is a separate distortion model 1316a 1316b for each path. In this example, both models share the same type of input terms and the same polynomial form, however the coefficients of the polynomial are different for each path. This is because the distortion differs slightly between paths. The output of this nonlinear model block is an error estimate of the nonlinear distortion for each channel. This estimate is subtracted 1318a 1318b from the original, ‘raw’ samples to form the corrected samples for each channel.

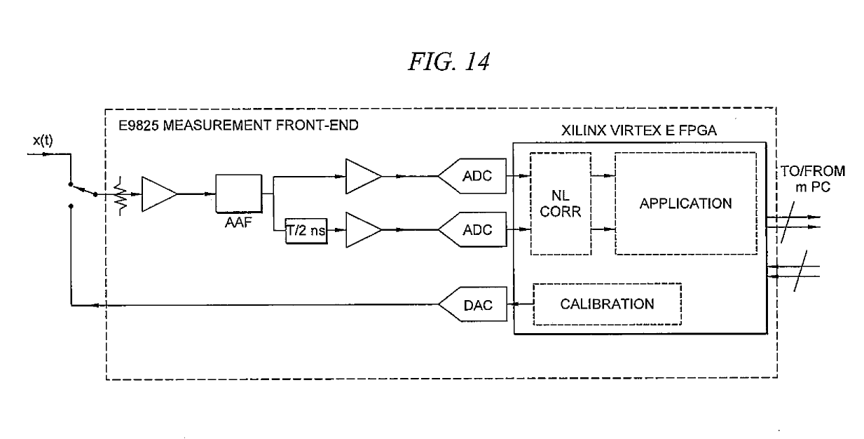

The model of FIG. 13 shows an exemplary model compiled from VHDL. Once in a hardware description language form, the NLC algorithm is merged with the other application hardware residing in the instrument's FPGA. As shown in FIG. 14, the FPGA distortion compensation occurs as a post-processing block that operates on raw ADC data. This combination of NLC and system application is typical of the intented instrument based nonlinear distortion compensation. The block diagram of FIG. 14 dipicts the prototyped NLC algorithm.

In this example, the following approximations act to simplify the generation of the model terms (use of alternate ADC as one-half sample delay), or reduce the model complexity by limiting the range of operation (using a high pass filter):
(i) Use of alternate ADC as one-half sample delay, approximation to the true analytic one-half sample delay that our distortion model is based on.
(ii) Highpass filter, slope filters=>feed main correction model. (filters may be polyphase to allow for cycle time limitations in implementation technology) In addition, the hardware implementation includes dithering to lowered quantization error related spurs, reloadable model coefficients, and simple ADC channel balancing.

Note that any of the functions described herein may be implemented in hardware, software, and/or firmware, and/or any combination thereof. When implemented in software, the elements of the present invention are essentially the code segments to perform the necessary tasks. The “processor readable medium” may include any medium that can store or transfer information. Examples of the processor readable medium include an electronic circuit, a semiconductor memory device, a ROM, a flash memory, an erasable ROM (EROM), a floppy diskette, a compact disk CD-ROM, an optical disk, a hard disk, a fiber optic medium, etc. The code segments may be downloaded via computer networks such as the Internet, Intranet, etc.

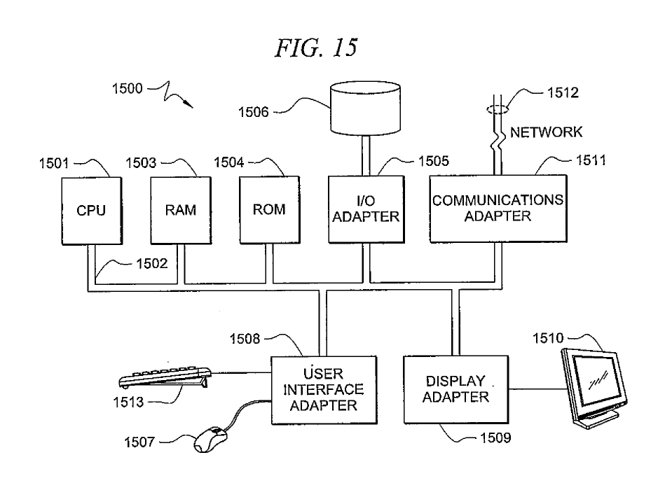

FIG. 15 illustrates computer system 1500 adapted to use the present invention. Central processing unit (CPU) 1501 is coupled to system bus 1502. The CPU 1501 may be any general purpose CPU, such as an Intel Pentium™ processor. However, the present invention is not restricted by the architecture of CPU 1501 as long as CPU 1501 supports the inventive operations as described herein. Bus 1502 is coupled to random access memory (RAM) 1503, which may be SRAM, DRAM, or SDRAM. ROM 1504 is also coupled to bus 1502, which may be PROM, EPROM, or EEPROM. RAM 1503 and ROM 1504 hold user and system data and programs as is well known in the art.

Bus 1502 is also coupled to input/output (I/O) controller card 1505, communications adapter card 1511, user interface card 1508, and display card 1509. The I/O adapter card 1505 connects to storage devices 1506, such as one or more of a hard drive, a CD drive, a floppy disk drive, a tape drive, to the computer system. The I/O adapter 1505 is also connected to printer 1514, which would allow the system to print paper copies of information such as document, photographs, articles, etc. Note that the printer may a printer (e.g. dot matrix, laser, etc.), a fax machine, or a copier machine. Communications card 1511 is adapted to couple the computer system 1500 to a network 1512, which may be one or more of a telephone network, a local (LAN) and/or a wide-area (WAN) network, an Ethernet network, and/or the Internet network. User interface card 1508 couples user input devices, such as keyboard 1513, pointing device 1507, and microphone 1516, to the computer system 1500. User interface card 1508 also provides sound output to a user via speaker(s) 1515. The display card 1509 is driven by CPU 1501 to control the display on display device 1510. The display 1510 may be used to output a representation of various signals used in the embodiments of the present invention as may be desired by a user.

Although embodiments and advantages of the subject matter of the present application have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, means, methods and steps described in the specification. As one of ordinary skill in the art would readily appreciate from the disclosure of the present application, processes, machines manufacture, means, methods, or steps, presently existing or later to be developed that perform substantially the same function or achieve substantially the same result as the corresponding embodiments described herein may be utilized according to the present application. Accordingly, the appended claims are intended to include within their scope such processes, machines, manufacture, means, methods, or steps.

What is claimed is:

1. A method to reduce nonlinear signal distortion within an electronic device, the method comprising:
applying at least one stimulus signal to the electronic device to excite and measure the resulting distortion;
analyzing nonlinear effects in the distorted stimulus signal;
modeling the distortion as a function of the stimulus signal; and
creating a correction signal using the modeled distortion.

2. The method of claim 1 further comprising the step of first, receiving a primary signal at an input of the electric device and applying said correction signal to said primary signal.

3. The method of claim 2 further comprising sampling the primary signal with multiple analog to digital converters.

4. The method of claim 1 further comprising the steps of:
generating a primary signal by the electronic device;
and applying said correction signal to said primary signal to create a compensated signal.

5. The method of 4 further comprising transmitting the compensated signal.

6. The method of 5 further comprising converting the sum of the primary and correction signal with multiple digital to analog converters.

7. The method of claim 1 wherein the step of modeling distortion as a function of the stimulus signal includes selecting a function that is linked to one or more physical phenomena.

8. The method of claim 1 wherein the step of analyzing the nonlinear effects of the distorted stimulus signal includes determining the analytical representation of the stimulus signal.

9. The method of claim 1 wherein the step of modeling the distortion as a function of the stimulus signal includes transforms of the analytical representation of the stimulus.

10. An apparatus comprising:
an electronic component configured to process a primary signal in the time domain, the electronic component comprising:
circuitry to apply one or more stimulus signals to the electronic device to excite distortion;
circuitry to model the distortion as a function of the stimulus signals; and
circuitry to create a correction signal using the distortion model;
wherein the electronic component is configured to use the correction signal to compensate for nonlinear signal distortion of the primary signal caused by the electronic component.

11. The apparatus of claim 10 wherein the apparatus is a digitizer configured to propagate the one or more primary signals while causing minimal nonlinear distortion within the digitizer.

12. The apparatus of claim 10 wherein the circuitry to apply one or more stimulus signals is configured to apply one or more of the following transforms: the first time derivative of the primary signal, the second time derivative of the primary signal, the integral of the primary signal, the absolute value of the primary signal, and one or more time delays at various times of the primary signal.

13. The apparatus of claim 12 wherein the circuitry to model distortion is configured to select one of the stimulus signals that capture nonlinear behavior.

14. The apparatus of claim 10 wherein the circuitry to model distortion is configured to approximate error phase space using at least one of the following: a polynomial, a look up table, an interpolated look up table, and a neural network.

15. The apparatus of claim 10 wherein the electronic component is configured to compensate for a primary signal that is interleaved using multiple analog to digital converters.

16. A computer program product stored in a computer readable medium, the program product configured to compensate for nonlinear distortion of a primary signal in an electronic device, the program product comprising:
code for applying one or more transforms to the electronic device;
code for selecting transforms that capture nonlinear behavior of the electronic device;
code for approximating error phase space to model the nonlinear distortion using the selected transforms; and
code for producing a correction signal to apply to the primary signal.

17. The program product of claim 16 further comprising, code for applying the correction signal to the primary signal.

18. The program product of claim 16 wherein the code for approximating error phase space uses at least one of the following for making the approximation: a polynomial, a look up table, an interpolated look up table, and a neural network.

19. The program product of claim 16 wherein the code for applying one or more transforms to the electronic device includes code for applying one or more of the following: the first time derivative of the primary signal, the second time derivative of the primary signal, the integral of the primary signal, the absolute value of the primary signal, and one or more time delays at various times of the primary signal.

20. The program product of claim 16 wherein the code for selecting transforms that capture nonlinear behavior includes code for selecting a transform that is linked to a physical phenomena.
